(19) United States
(12) Patent Application Publication
(10) Pub. No.: US 2026/0238120 A1
(43) Pub. Date: Aug. 13, 2026

(54) POWER CONVERTER TEMPERATURE MANAGEMENT IN ELECTRIC VEHICLE PROPULSION DRIVE SYSTEM

(71) Applicant: FORD GLOBAL TECHNOLOGIES, LLC, Dearborn, MI (US)

(72) Inventors: Jogendra Singh Thongam, Windsor (CA); Baoming Ge, Okemos, MI (US); Shengnan Zhu, Allen Park, MI (US); Trevor Parent, Windsor (CA); Steven Bradford, Trenton, MI (US); Kevin Lloyd Newman, Farmington Hills, MI (US); Milind B. Kulkarni, Livonia, MI (US)

(21) Appl. No.: 19/048,278

(22) Filed: Feb. 7, 2025

(51) Int. Cl. B60L 50/51; H01L 23/34; H01L 23/373; H01L 23/473; H02M 1/14; H02M 1/32; H02M 1/36; H05K 7/20; H10D 62/832

(52) U.S. Cl. CPC H02M 1/327; H02M 1/14; H02M 1/36; H05K 7/20945; H10W 40/00; H10W 40/255; H10W 40/47; H10D 62/8325

(57) ABSTRACT

An automotive system includes a power converter with a switch having a junction and a temperature sensor positioned proximate to the switch. Responsive to a temperature of the junction, which is different than temperatures detected by the temperature sensor, exceeding a predetermined threshold, a controller reduces power output of the power converter.

### TECHNICAL FIELD

This disclosure relates to thermal management systems for power converters used in electric vehicles.

### BACKGROUND

An electric vehicle may use electrical energy to power an electric machine. A power converter may process electrical energy and convert the electrical energy to an appropriate form. During operation, power converters may generate heat.

### SUMMARY

A vehicle includes a traction battery, a motor, and a power converter electrically connecting the two. The power converter includes a power semiconductor chip and a temperature sensor, both mounted on the same substrate but spaced apart, with the chip lacking an on-chip temperature sensor. A controller is programmed such that if a junction temperature of the power semiconductor chip exceeds a threshold, the controller reduces the power output of the power converter.

A method involves reducing a power output of a power converter if a junction temperature of a power transistor that lacks an on-chip temperature sensor surpasses a threshold.

A vehicle power system includes a power converter with multiple power transistors, all of which lack on-chip temperature sensors. A substrate temperature sensor and a coolant temperature sensor are used for thermal monitoring, with the substrate sensor mounted on the same substrate as one of the power transistors but spaced apart. A controller is programmed to shut down the power converter or individual transistors if a junction temperature of any transistor exceeds a threshold.

### BRIEF DESCRIPTION OF THE DRAWINGS

FIG. 1 is a schematic diagram of an electric vehicle including a power converter.

FIG. 2 is a plan view of a semiconductor chip of a power transistor and a temperature sensor mounted to a same substrate.

FIG. 3A is a block diagram for detecting power converter over-temperature and coolant loop issues, including a first lookup table and a second lookup table.

FIG. 3B is a flow chart for detecting power converter over-temperature and coolant loop issues.

FIGS. 4 and 5 are graphical representations of the difference in temperature between the junction of a semiconductor chip mounted to a substrate and the temperature of a temperature sensor mounted to the same substrate under various coolant flow rates.

FIG. 6 is a graphical representation of the difference in temperature between the junction of a semiconductor chip mounted to a substrate and the temperature of a temperature sensor mounted to the same substrate under various coolant temperatures and various power loss conditions.

FIG. 7 is graphical representation of power converter output versus junction temperature.

### DETAILED DESCRIPTION

Embodiments are described herein. The disclosed embodiments, however, are merely examples and other embodiments may take various and alternative forms. The figures are not necessarily to scale. Some features could be exaggerated or minimized to show details of particular components. Therefore, specific structural and functional details disclosed herein are not to be interpreted as limiting, but merely as a representative basis for teaching one skilled in the art.

Various features illustrated and described with reference to any one of the figures may be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

Cooling the power converter in an electric vehicle (EV) propulsion drive system can be important for at least the reason to optimize the power delivery capability of the system. The power converter controls the transfer of electrical energy between the battery and the electric motor, converting the battery's electrical output into an appropriate form for motor operation. For instance, it may convert DC power from the battery into AC power for the motor. The power converter uses power devices to condition the electrical energy. A power device may be configured as a Silicon Carbide Metal Oxide Semiconductor Field-Effect Transistor (SiC MOSFET) or as a Silicon Insulated Gate Bipolar Transistors (Si IGBTs), among others. SiC MOSFETs, in particular, function as high-speed switches within the power converter, providing minimal conduction losses, high-voltage handling capability, and perform well under elevated thermodynamic conditions. The power converter may incorporate multiple power devices in its configuration.

A coolant loop system may be configured to extract heat from individual power devices, multiple power devices, or an entire power converter. A controller can monitor and maintain the required coolant flow rate and temperature parameters to ensure the EV propulsion drive system operates within its designed power capacity. However, the thermodynamic response rate of the coolant loop may be slower than that of the power devices or power converter, potentially delaying the detection of an improper thermodynamic state by the controller. This delay can lead to heating of a power device or a power converter. Detecting an improper thermodynamic state of a power device or power converter in an EV propulsion drive system can involve identifying (i) over-temperature conditions of the power device or power converter or (ii) coolant flow issues. While coolant flow issues can induce over-temperature conditions, overheating can occur independently of coolant flow issues.

An EV propulsion drive system using a power device configured as a Si IGBT may incorporate an on-die temperature sensor within the Si IGBT, enabling the controller to detect over-temperature conditions based on temperature data directly from the sensor. However, for an EV propulsion drive system using a power device configured as a SiC MOSFET, integrating an on-die temperature sensor into the SiC MOSFET can increase complexity. In the absence of an integrated on-die temperature sensor, detecting over-temperature conditions in the SiC MOSFET power device becomes more challenging.

The present technology discloses devices, systems, and methods for detecting over-temperature and coolant flow issues in power converters having SiC MOSFET based power devices, without integrating on-die temperature sensors into the SiC MOSFET based power devices. For example, a device may include a power device configured as a SiC MOSFET mounted on a substrate, with a temperature sensor positioned on the same substrate in close proximity to and centered on the SiC MOSFET. A system may incorporate a controller with the capability to evaluate the junction temperature of a SiC MOSFET. If the controller determines that the junction temperature exceeds a predetermined threshold due to over temperature, it may derate the torque output of the EV's drive motor to preclude the power device or power converter from experiencing over-temperature conditions, or the controller may deactivate the power device or power converter. In other embodiments, if the controller identifies that the temperature of the junctions exceeds a predetermined threshold value due to coolant flow issues, it may derate the torque output of the EV's drive motor, or the controller may deactivate the power device or power converter.

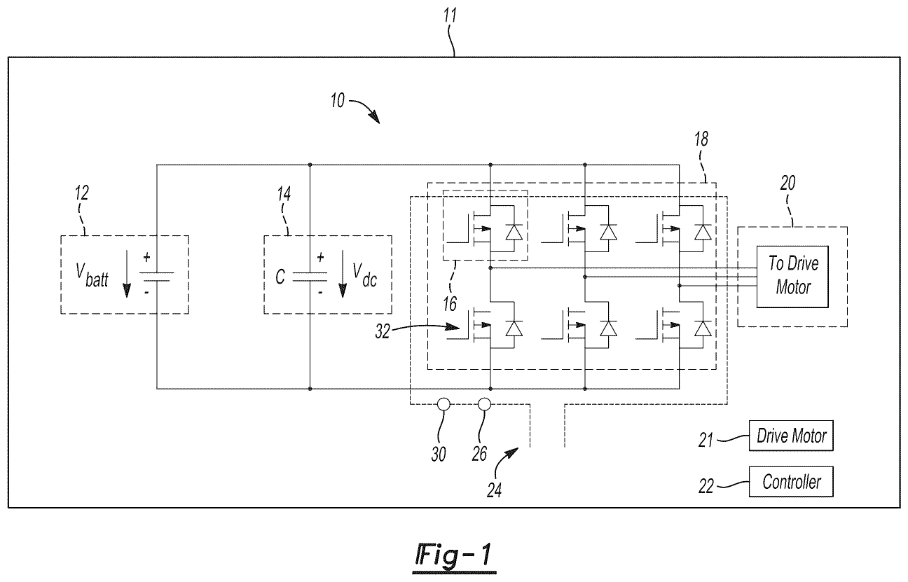

Referring to FIG. 1, an EV propulsion drive system 10 of an EV 11 includes a traction battery 12, a capacitor 14, a plurality of power devices 16 arranged to form a power converter 18, and a system 20 suitable to provide a drive motor 21 with the power output from power converter 18. The traction battery 12 has a voltage V_{batt} and the capacitor 14 has a voltage of V_{dc}. The capacitor 14 may smooth out energy fluctuations to the power converter 18 from the traction battery 12 and other systems of the EV 11, such as a regenerative braking system (not depicted). The traction battery 12 and capacitor 14 can provide electrical energy to power converter 18. The power devices 16 may be configured as SiC MOSFETs or other suitable switching devices. The power converter 18 converts electrical energy from traction battery 12 and capacitor 14 to a suitable form for the drive motor 21. For example, the traction battery 12 may provide electrical energy in DC form and the power converter 18 may convert the DC electrical energy into AC electrical energy. The power devices 16 are operated through their respective gate drive circuits 32 and may generate heat during operation.

The heat from the power devices 16 can be dissipated, in part, through coolant loop 24. The coolant loop 24 may have multiple configurations beyond what is depicted in FIG. 1. For example, the coolant loop 24 may have a path that enables the withdrawal of heat from each of the power devices 16 through a heat exchanger (not depicted) at each of the power devices 16. As another example, the coolant loop 24 may be designed to extract heat from the power converter 18 as a whole through an individual heat exchanger (not depicted) or a series of heat exchanges (not depicted). In some embodiments, no heat exchangers are used. The coolant loop 24 may have a coolant inlet temperature sensor 26 that measures the temperature of the coolant before the coolant extracts heat from one or more of the power devices 16 or the power converter 18. In some embodiments, the coolant loop 24 may also have a coolant flow meter 30 measuring the flow rate of the coolant in the coolant loop 24. Controller 22 can have infrastructure to receive temperature data from the coolant inlet temperature sensor 26 and coolant flow meter 30. In some embodiments, the controller 22 can also have infrastructure to receive power loss data from the power converter 18 or power loss data from power device 16. The technology disclosed herein does not require the controller 22 to receive temperature data or power loss data from each sensor described, as in some embodiments not all of the sensors are present. For example, in some embodiments, the controller 22 uses temperature data from the coolant inlet temperature sensor 26 and power loss data from the power devices 16 or power converter 18 and does not use flow rate data from the flow meter 30.

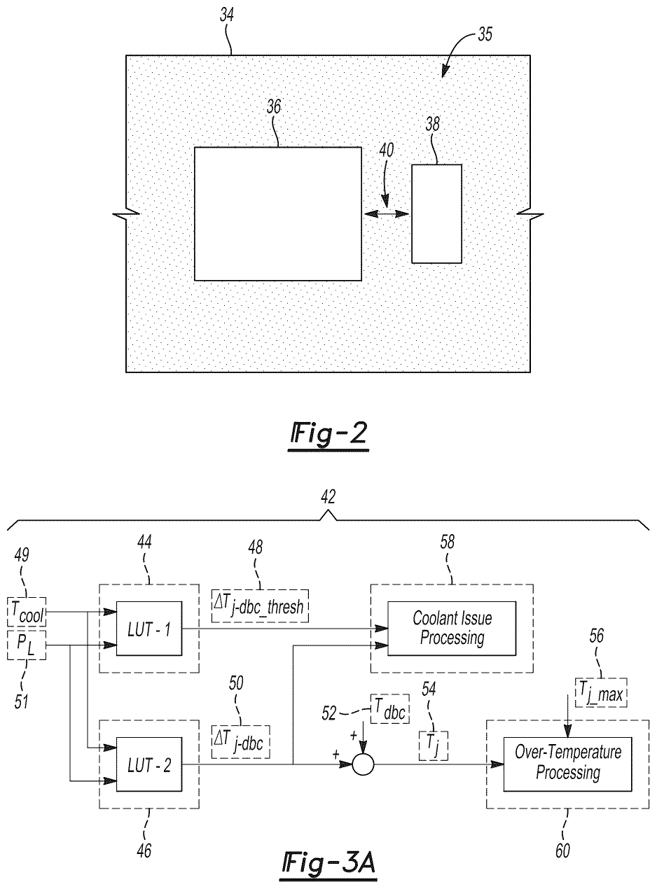

Referring to FIG. 2, a SiC MOSFET 36 (an example of the power device 16) is mounted to substrate 34. The substrate 34 may include a direct bonded copper (DBC) layer 35. In certain embodiments, the SiC MOSFET 36 is bonded to the DBC layer 35 using appropriate methods such as epoxy or solder bonding. A DBC temperature sensor 38 is mounted to the substrate 34 by bonding it to the DBC layer 35 using suitable techniques like epoxy or solder bonding. The DBC temperature sensor 38 is configured to measure the temperature of the DBC layer 35. In some embodiments, the DBC temperature sensor 38 is a negative temperature coefficient (NTC) sensor or a platinum (PT) 1000 sensor, among others. The DBC temperature can serve as a variable for accurately determining the junction temperature of the SiC MOSFET 36.

It may be advantageous to position the DBC temperature sensor 38 and SiC MOSFET 36 centrally on the substrate 34. However, in some configurations, the semiconductor chip 36 may not be centered on the substrate 34. In such cases, the DBC temperature sensor 38 can be aligned, with reference to the figure, either vertically or horizontally with respect to the SiC MOSFET 36. It may also be beneficial for distance 40 between the DBC temperature sensor 38 and SiC MOSFET 36 to be minimized while still satisfying the insulation requirements of the SiC MOSFET 36.

As previously discussed, directly measuring the junction temperature of a semiconductor chip, such as a SiC MOSFET, can be challenging. However, by using a temperature sensor (e.g., the DBC temperature sensor 38) mounted to a substrate (e.g., the substrate 34) the sensor's temperature readings can be leveraged to derive the junction temperature of a SiC MOSFET (e.g., the SiC MOSFET 36) also mounted on the same substrate. Temperature data from a DBC temperature sensor can be denoted as T_{dbc}, and the junction temperature of a SiC MOSFET can be denoted as Tⱼ. The temperature difference between the junction of a SiC MOSFET, such as the SiC MOSFET 36, and temperature of the DBC temperature sensor, such as the DBC temperature sensor 38, can be denoted as ΔT_{j-dbc}.

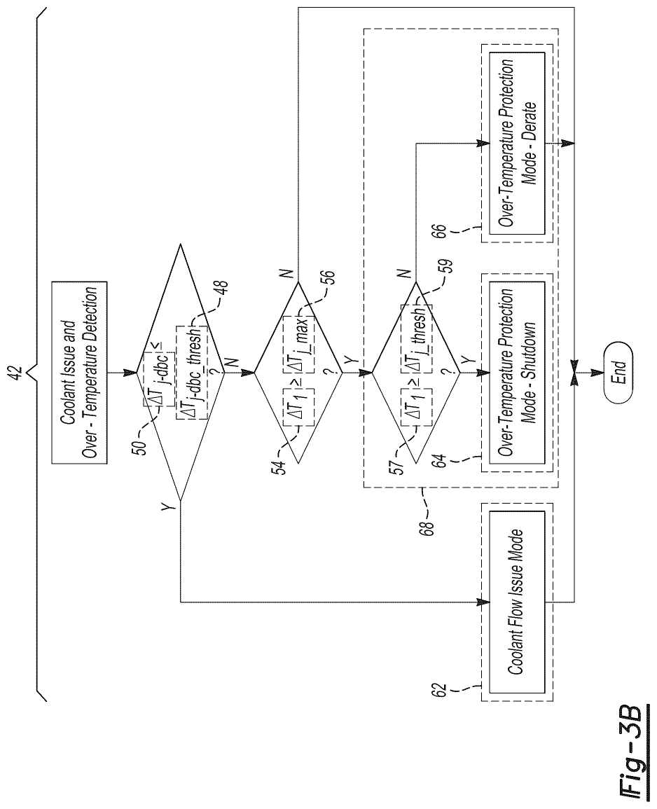

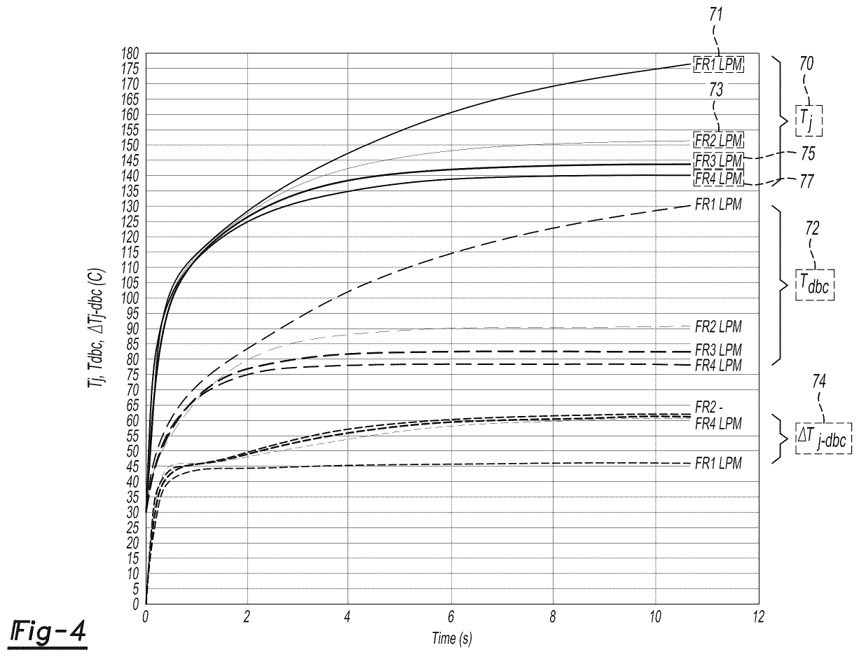

Referring to FIG. 3A, the system 42, which can be implemented by the controller 22, can include a first look up table 44 and a second look up table 46. The look up table 44 is used to determine ΔT_{j-dbc-threshold} 48, a threshold temperature differential between the junction of a SiC MOSFET and temperature of a DBC temperature sensor. For example, ΔT_{j-dbc-threshold} 48 can be a threshold temperature differential between the junction of the SiC MOSFET 36 and a temperature indicated by the DBC temperature sensor 38. The look up table 44 uses coolant temperature data 49 and power loss data 51 and outputs ΔT_{j-dbc-threshold} 48.

A lookup table, in some examples, is a structured data repository designed to store predefined values for retrieval based on specific input parameters. A lookup table maps or indexes input parameters to corresponding output parameters. In scenarios where the input parameters do not precisely match predefined values, interpolation techniques can be used to estimate the output parameters accurately.

The look up table 46 uses the coolant temperature data 49 and power loss data 51 and outputs ΔT_{j-dbc} 50. The system 42 can also include receiving temperature data T_{dbc} 52. By way of an example, T_{dbc} 52 can be the temperature data of the DBC temperature sensor 38. Tⱼ 54 is the junction temperature of a SiC MOSFET based power device. By way of an example, Tⱼ 54 can be the temperature of the SiC MOSFET 36. Tⱼ 54 can be derived by summing T_{dbc} 52 and ΔT_{j-dbc} 50. By way of an equation, Tⱼ 54=T_{dbc} 52+ΔT_{j-dbc} 50. Tⱼ₋ₘₐₓ 56 is a predefined input parameter representing the maximum allowable junction temperature for a power device. By way of an example, Tⱼ₋ₘₐₓ 56 can be the maximum operating temperature for the SiC MOSFET 36. In some embodiments, Tⱼ₋ₘₐₓ 56 can be, for example, 165° C. or another predetermined value. Coolant issue processing 58 can include receiving and comparing the value ΔT_{j-dbc-threshold} 48 and ΔT_{j-dbc} 50. Over-temperature processing 60 can include receiving and comparing Tⱼ 54 and Tⱼ₋ₘₐₓ 56.

Referring to FIG. 3B, in the system 42 if ΔT_{j-dbc-threshold} 48 is greater than ΔT_{j-dbc} 50, as determined in the coolant issue processing 58, the system 42 activates coolant flow issue mode 62. The coolant flow issue mode 62 can include derating motor torque control of the drive motor. By way of example, the drive motor 21 may have a derating motor torque control. The coolant flow issue mode 62 can also include shutting down the power converter 18. By way of an example, the power converter 18 may be shutdown. Further, the coolant flow issue mode 62 can also include shutting down an individual power device of the power converter 18. By way of an example, one or more of the power devices 16 may be disabled.

If ΔT_{j-dbc-threshold} 48 is less than ΔT_{j-dbc} 50 as determined by the coolant issue processing 58, the system 42 then determines in the over-temperature processing 60 whether to activate over-temperature protection mode 68. The over-temperature protection mode 68 can include over-temperature protection mode-shutdown 64 and over-temperature protection mode-derate 66. If both T_{j-dbc-threshold} 48 is less than ΔT_{j-dbc} 50 and Tⱼ 54 is less than Tⱼ₋ₘₐₓ 56, then the system 42 does not detect a coolant flow issue or over-temperature issue and does not derate motor torque control, does not shutdown a power converter, or does not shutdown a power device.

If however ΔT_{j-dbc-threshold} 48 is less than ΔT_{j-dbc} 50 as determined by the coolant issue processing 58, and Tⱼ 54 is greater than Tⱼ₋ₘₐₓ 56, as determined by the over-temperature process 60, the system 42 activates the over-temperature protection mode 68. In this mode, it may be advantageous for the system to differentiate between power converter shutdown and motor torque control derating, particularly because the power device junction may operate above its optimal temperature without yet reaching a threshold temperature. In cases where the junction temperature is above the optimal range but below a certain level, the power device can continue to provide power but at a derated level. This derating may suffice to reduce the junction temperature back to an optimal range. Over-temperature protection differs from coolant flow issue protection because coolant flow issues can more rapidly lead to higher junction temperatures. In such scenarios in coolant flow issues, distinguishing between junction temperatures above optimal but below other thresholds may not be necessary.

In the over-temperature protection mode 68, the system 42 compares ΔTⱼ 57 to ΔT_{j-threshold} 59. ΔTⱼ 57 is the difference between Tⱼ 54 and Tⱼ₋ₘₐₓ 56, and ΔT_{j-threshold} 59 is a predetermined value. If ΔTⱼ 57 is greater than ΔT_{j-threshold} 59, the system 42 in the over-temperature protection mode 68 activates the over-temperature protection mode-shutdown 64. By way of an example, the power converter 18 may be shutdown. Further, the over-temperature protection 68 can also include shutting down an individual power device of a power converter. By way of an example, one of the power devices 16 may be shutdown.

If ΔTⱼ 57 is less than ΔT_{j-threshold} 59, the system 42 in the over-temperature protection 68 activates the over-temperature protection mode-derate 66. By way of example, the drive motor 21 may have a derating motor torque control.

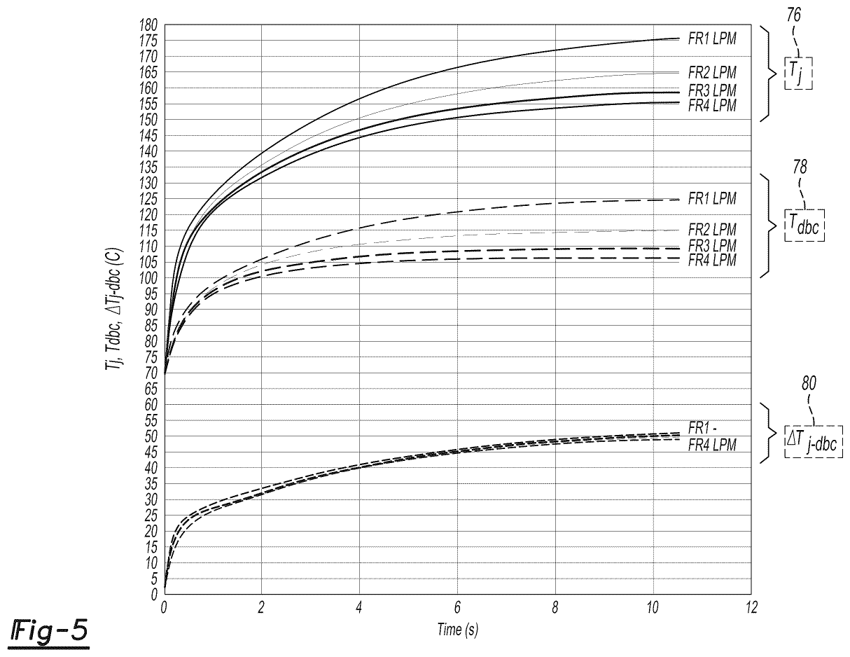

FIG. 4 depicts the results of coolant flow issues to an EV's power device, where each power device operates at the same power output but coolant flow rate through the power device or power converter varies. In FIG. 4, Flow Rate 1 (“FR1”) 71 is set to 0 LPM, while FR2 73, FR3 75, and FR4 77 are set to non-zero values, such that FR1 71 is less than FR2 73, which is less than FR3 75, and FR3 75 is less than FR4 77. The temperature curves are grouped into three groups. First, Tⱼ 70, as measured by an infrared camera, or other non-invasive temperature sensing method, is the temperature of a junction of a power device's semiconductor. Second, T_{dbc} 72 is the temperature of a DBC sensor. By way of example, T_{dbc} 72 may be the temperature of the temperature sensor 38. Third, ΔT_{j-dbc} 74 is the calculated difference between Tⱼ 70 and T_{dbc} 72. As shown, for flow rates FR2-FR4, the ΔT_{j-dbc} 74 remains relatively constant for each flowrate. But when the flow rate is set to zero, i.e., FR1 71, the ΔT_{j-dbc} 74 curve deviates from the other ΔT_{j-dbc} 74 curves for FR2-FR4. If ΔT_{j-dbc} 74 is less than a predetermined threshold, coolant flow issues are detected. ΔT_{j-dbc} 74 can therefor be characterized, in part, to indicate coolant flow issues to an EV's power device. Coolant temperature in FIG. 4 is set to 30 deg C., but other temperatures are possible and the same behavior of Tⱼ 70, T_{dbc} 72, and ΔT_{j-dbc} 74 can be observed.

FIG. 5 depicts overtemperature of an EV's power device under normal coolant flow. More particularly, FIG. 5 shows an example of the junction temperature of a power device's semiconductor exceeding a threshold value, Tⱼ₋ₘₐₓ (not depicted), under normal coolant flow rate. Tⱼ₋ₘₐₓ can be set at any predetermined value, for example it can be 165 deg C. FR1 is not set to zero LPM in FIG. 5, but the relationship that FR1 is less than FR2, FR2 is less than FR3, and FR3 is less than FR4 still holds true. The curves are grouped into three groups. First, Tⱼ 76, as measured by an infrared camera, or other non-invasive temperature sensing method, is the temperature of a junction of a power device's semiconductor. Second, T_{dbc} 78 is the temperature of a DBC sensor. Third, ΔT_{j-dbc} 80 is the difference between Tⱼ 76 and T_{dbc} 78. If one of the curves in Tⱼ 76, such as the one associated with FR1 exceeds the Tⱼ₋ₘₐₓ, a derating action of motor torque can be executed. If Tⱼ 76 continues to increase such that a ΔTⱼ Tⱼ 76 and Tⱼ₋ₘₐₓ (not depicted), is greater than (not a ΔT_{j-threshold}, depicted), the calculated power device as a difference or power converter between may be shutdown. ΔT_{j-threshold} may be a predetermined number, for example 5 deg C.

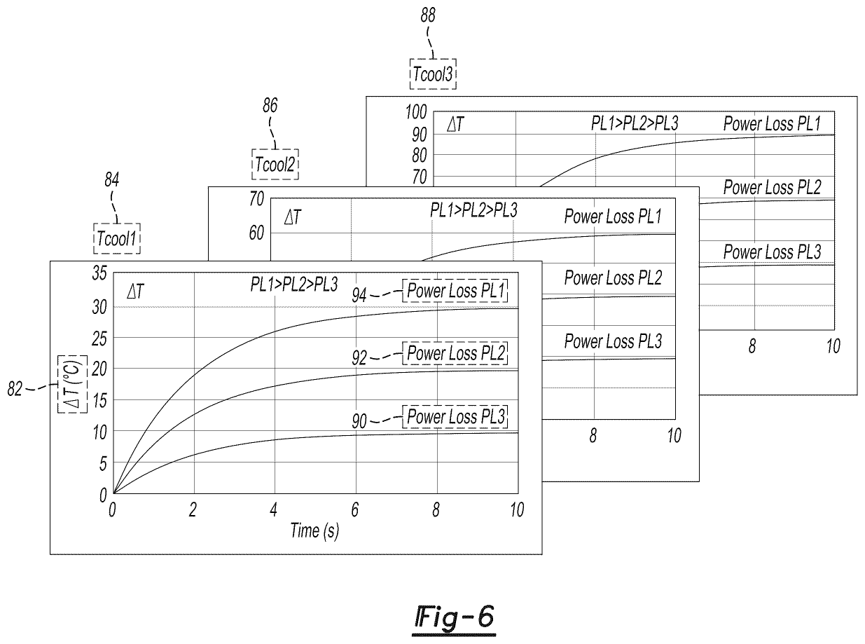

FIG. 6 depicts the ΔT_{j-dbc} 82 at various coolant temperatures. For example, coolant temperatures can be Tcool1 84, Tcool2 86, or Tcool3 88. ΔT_{j-dbc} can be a function a of power loss (PL) and coolant temperature. In some embodiments, PL1 94 is greater than PL2 92, and PL2 92 is greater than PL3 90. Other coolant temperatures beside Tcool1 84, Tcool2 86, and Tcool3 88 are possible. ΔT_{j-dbc} is shown on the y-axis for each coolant temperature. Power loss in a power device like a SiC MOSFET can be the energy dissipated as heat due to inefficiencies during operation, among others. Power loss can include losses from conduction, switching, gate drive, and leakage. Tⱼ, the temperature of a junction in a power device, can increase as power loss increases. Put differently, and as shown in FIG. 6, where PL1 94 is greater than PL2 92, and PL2 92 is greater than PL3 90, ΔT_{j-dbc} 82 decreases as power loss decreases. Further, Tⱼ can increase as coolant temperature increases. Put differently, and as shown in FIG. 6, where Tcool3 88 is greater than Tcool2 86, and Tcool2 86 is greater than Tcool1 84, ΔT_{j-dbc} 82 increases with coolant temperature at a given power loss. Therefore, ΔT_{j-dbc} can be determined by the power losses at various coolant temperatures. When T_{dbc}, as described with respect to FIG. 2, is a known temperature, it becomes possible to determine Tⱼ as Tⱼ can be equal to T_{dbc} plus ΔT_{j-dbc}. It can therefore be possible to determine Tⱼ without measuring Tⱼ directly or indirectly or relying on a thermal model.

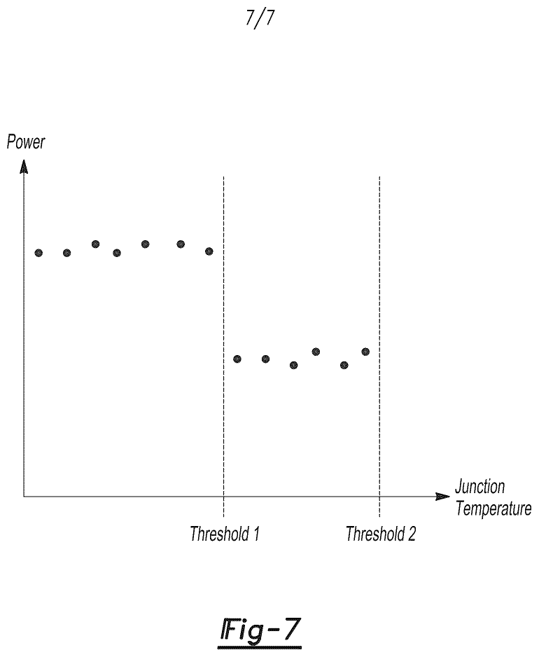

FIG. 7 depicts power converter output as a function of junction temperature. The output drops once the junction temperature exceeds Threshold 1. The output then ceases once the junction temperature exceeds Threshold 2.

To determine whether the techniques described above are being used in circumstances in which the related data (e.g., power loss, etc.) is not easily accessible, the junction temperature can be determined by non-invasive techniques such as infrared cameras, which measure thermal radiation from the device's surface. Spot pyrometers or infrared sensors can also be used to provide localized temperature readings. Microscale thermal sensing methods, such as micro-Raman spectroscopy can also detect junction temperatures. Alternatively, optical pyrometry can be used to measure emitted radiation from the device at specific wavelengths. Further, scanning thermal microscopy can be used for high-resolution surface temperature mapping. Any of these methods, or other appropriate technique, can be used to measure the temperature of a power device's junction to assess whether the relationship with power converter output is present.

The algorithms, methods, or processes disclosed herein can be deliverable to or implemented by a computer, controller, or processing device, which can include any dedicated electronic control unit or programmable electronic control unit. Similarly, the algorithms, methods, or processes can be stored as data and instructions executable by a computer or controller in many forms including, but not limited to, information permanently stored on non-writable storage media such as read only memory devices and information alterably stored on writeable storage media such as compact discs, random access memory devices, or other magnetic and optical media. The algorithms, methods, or processes can also be implemented in software executable objects. Alternatively, the algorithms, methods, or processes can be embodied in whole or in part using suitable hardware components, such as application specific integrated circuits, field-programmable gate arrays, state machines, or other hardware components or devices, or a combination of firmware, hardware, and software components.

While exemplary embodiments are described above, it is not intended that these embodiments describe all possible forms encompassed by the claims. Moreover, the words used in the specification are words of description rather than limitation, and various changes may be made without departing from the spirit and scope of these disclosed materials. The terms controller and controllers, for example, can be used interchangeably herein.

What is claimed is:

1. A vehicle comprising:
a traction battery;
a motor;
a power converter electrically connected between the traction battery and motor, and including a power semiconductor chip and a temperature sensor spaced apart from one another and mounted on a same substrate such that the power semiconductor chip lacks an on-chip temperature sensor; and
a controller programmed to, responsive to temperature of a junction of the power semiconductor chip exceeding a first threshold, reduce a power output of the power converter, wherein the temperature of the junction is different than a temperature detected by the temperature sensor.

2. The vehicle of claim 1, wherein the controller is further programmed to, responsive to the temperature of the junction exceeding a second threshold greater than the first threshold, shutdown the power semiconductor chip or power converter.

3. The vehicle of claim 1, wherein the temperature sensor is centered on the power semiconductor chip.

4. The vehicle of claim 1, wherein the substrate includes direct bonded copper.

5. The vehicle of claim 1, wherein the temperature sensor is a negative temperature coefficient sensor.

6. The vehicle of claim 1 further comprising a coolant temperature sensor.

7. The vehicle of claim 6, wherein the temperature of the junction is a function of a temperature detected by the coolant temperature sensor.

8. The vehicle of claim 1, wherein the temperature of the junction is a function of a power loss associated with the power converter.

9. A method comprising:
reducing a power output of an automotive power converter according to a temperature of a junction of a power transistor of the automotive power converter that lacks an on-chip temperature sensor.

10. The method of claim 9 further comprising shutting down the automotive power converter according to the temperature.

11. The method of claim 9 further comprising reducing the power output according to a difference between the temperature of the junction and a temperature of a substrate on which the power transistor is mounted.

12. A vehicle power system comprising:
a power converter including a plurality of power transistors all lacking on-chip temperature sensors, a substrate temperature sensor spaced away from one of the power transistors and mounted on a same substrate as the one of the power transistors, and a coolant sensor configured to detect a temperature of a coolant for the power converter; and
a controller programmed to shut down the power converter or at least one of the power transistors responsive to a temperature of a junction of the least one of the power transistors exceeding a threshold, wherein the temperature of the junction is different than temperatures detected by the substrate temperature sensor and the coolant temperature sensor.

13. The vehicle power system of claim 12, wherein the controller is further programmed to reduce a power output of the power converter responsive to the temperature of the junction exceeding another threshold.

14. The vehicle power system of claim 12, wherein the substrate temperature sensor is centered on the one of the power transistors.

15. The vehicle power system of claim 12, wherein the substrate includes direct bonded copper.

16. The vehicle power system of claim 12, wherein the temperature of the junction is a function of the temperature detected by the substrate temperature sensor.

17. The vehicle power system of claim 12, wherein the temperature of the junction is a function of the temperature detected by the coolant temperature sensor.

18. The vehicle power system of claim 12, wherein the temperature of the junction is a function of a power loss of the power converter.

19. The vehicle power system of claim 12, wherein the controller is further programmed to reduce a power output of the power converter responsive to a difference between the temperature of the junction and the temperature detected by the substrate temperature sensor.
